(19) United States
(12) Patent Application Publication
(10) Pub. No.: US 2020/0389158 A1
(43) Pub. Date: Dec. 10, 2020

(54) SEMICONDUCTOR DEVICE AND CLOCK SYSTEM INCLUDING PULSE LASER-BASED CLOCK DISTRIBUTION NETWORK

(71) Applicants: KOREA ADVANCED INSTITUTE OF SCIENCE AND TECHNOLOGY, Daejeon (KR); KOREA UNIVERSITY RESEARCH AND BUSINESS FOUNDATION, SEJONG CAMPUS, Sejong-si (KR)

(72) Inventors: Jungwon KIM, Daejeon (KR); Hayun Cecillia CHUNG, Daejeon (KR)

(73) Assignees: KOREA ADVANCED INSTITUTE OF SCIENCE AND TECHNOLOGY, Daejeon (KR); KOREA UNIVERSITY RESEARCH AND BUSINESS FOUNDATION, SEJONG CAMPUS, Sejong-si (KR)

(21) Appl. No.: 16/688,599

(22) Filed: Nov. 19, 2019

(30) Foreign Application Priority Data
Jun. 4, 2019 (KR) 10-2019-0066081

(51) Int. Cl. H03K 3/42; G06F 1/10

(52) U.S. Cl. CPC H03K 3/42; G06F 1/10

(57) ABSTRACT

Disclosed is a semiconductor device and a clock system including a pulse laser-based clock distribution network. The semiconductor device includes a current pulse generator that generates a current pulse train based on a first optical pulse train and a second optical pulse train, a clock distribution network that outputs a clock based on the current pulse train, a CDN detector that detects at least one of status information of the clock distribution network and the output clock to generate detection information, and control logic that generates a control signal for regulating a current of the current pulse train based on the detection information.

### CROSS-REFERENCE TO RELATED APPLICATIONS

This application claims priority under 35 U.S.C. § 119 to Korean Patent Application No. 10-2019-0066081 filed on Jun. 4, 2019, in the Korean Intellectual Property Office, the disclosure of which is incorporated herein by reference in its entirety.

### BACKGROUND

Example embodiments of the inventive concepts described herein relate to a semiconductor device and a clock system, and more particularly, relate to a semiconductor device and a clock system that include a pulse laser-based clock distribution network.

A semiconductor device may be implemented based on a semiconductor element such as a transistor. To miniaturize a semiconductor device performing a complicated function, the semiconductor device may be implemented with an integrated circuit where various elements are integrated. A clock being a periodical signal is used to synchronize circuit blocks of the integrated circuit, and the clock may be distributed all over the integrated circuit. There is desired a clock distribution network (CDN) to distribute the clock all over the integrated circuit.

When the clock distribution network supplies the clock all over the integrated circuit by using clock drivers, a jitter issue may occur due to a phase locked loop and a power noise, and a skew issue may occur in the clock distribution network due to the variation of process, voltage, and temperature. Also, power consumption and heat generation issues may occur due to the clock drivers.

### SUMMARY

Some example embodiments of the inventive concepts provide a semiconductor device and a clock system capable of minimizing jitter, skew, and power consumption issues in a clock distribution network.

According to an example embodiment, a semiconductor device includes a current pulse generator that generates a current pulse train based on a first optical pulse train and a second optical pulse train having different phases, a clock distribution network that outputs a clock based on the current pulse train, a clock distribution network (CDN) detector that detects at least one of status information of the clock distribution network and the output clock to generate detection information, and control logic that generates a control signal for regulating a current of the current pulse train based on the detection information.

In an example embodiment, the current pulse generator may include a first photodiode that generates a first current based on the first optical pulse train, and a second photodiode that generates a second current based on the second optical pulse train, and the current pulse train may be generated based on the first current and the second current.

In an example embodiment, the current pulse generator includes a first optical detector that generates a first current pulse train based on the first optical pulse train and the second optical pulse train, a first switch that selectively outputs the first current pulse train based on the control signal, a second optical detector that generates a second current pulse train based on the first optical pulse train and the second optical pulse train, and a second switch that selectively outputs the second current pulse train based on the control signal, and the current pulse train may be generated based on a signal output from the first switch and the second switch.

In an example embodiment, the status information of the clock distribution network may include at least one of load capacitance information, effective resistance information, and temperature information of the clock distribution network.

In an example embodiment, the CDN detector may detect a peak voltage of the output clock.

In an example embodiment, the control logic may generate the control signal based on a result of comparing the peak voltage of the clock and a reference magnitude.

In an example embodiment, the semiconductor device may further include a clamper that outputs a clock clamped such that a positive peak voltage of the output clock is maintained at a first reference voltage or smaller and a negative peak voltage of the output clock is maintained at a second reference voltage or greater.

In an example embodiment, the clock distribution network may be implemented with a metal layer having a mesh structure, an H-tree structure, or a combination thereof.

In an example embodiment, the clock distribution network may be a repeater-free clock distribution network.

In an example embodiment, the current pulse generator and the clock distribution network may be disposed on a single chip including an optical chip layer and an electronic chip layer of a stacked structure or an abutted structure, the current pulse generator may be disposed in the optical chip layer, and the clock distribution network may be disposed in the electronic chip layer.

In an example embodiment, when the first optical pulse train and the second optical pulse train have a first period, a phase difference of the first optical pulse train and the second optical pulse train may be half the first period.

According to an example embodiment, a clock system includes an optical pulse generating device that generates a first optical pulse train and a second optical pulse train having different phases, a current pulse generator that generates a current pulse train based on the first optical pulse train and the second optical pulse train, a clock distribution network that outputs a clock based on the current pulse train, a CDN detector that detects at least one of status information of the clock distribution network and the output clock to generate detection information, and control logic that generates a control signal for controlling an optical intensity of at least one of the first optical pulse train and the second optical pulse train based on the detection information.

In an example embodiment, the optical pulse generating device may include a pulse laser that outputs an optical pulse train, and an optical power regulator that generates the first optical pulse train and the second optical pulse train based on the optical pulse train, and the optical power regulator may regulate an optical intensity of at least one of the first optical pulse train and the second optical pulse train in response to the control signal.

In an example embodiment, the output optical pulse train may have a pulse width of a femtosecond or picosecond domain.

In an example embodiment, the status information of the clock distribution network may include at least one of load capacitance information, effective resistance information, and temperature information of the clock distribution network.

In an example embodiment, the CDN detector may detect a peak voltage of the output clock.

In an example embodiment, the control logic may generate the control signal based on a result of comparing the peak voltage of the clock and a reference magnitude.

According to an example embodiment, a clock system includes an optical pulse generating device that generates first to fourth optical pulse trains, a first current pulse generator that generates a first current pulse train based on the first optical pulse train and the second optical pulse train, a second current pulse generator that generates a second current pulse train based on the third optical pulse train and the fourth optical pulse train, a first clock distribution network that outputs a first clock based on the first current pulse train a second clock distribution network that outputs a second clock based on the second current pulse train, a CDN detector that detects at least one of first status information of the first clock distribution network and the output first clock to generate first detection information and detects at least one of second status information of the second clock distribution network and the output second clock to generate second detection information, and control logic that generates a first control signal for regulating a current of the first current pulse train based on the first detection information and generates a second control signal for regulating a current of the second current pulse train based on the second detection information.

In an example embodiment, the optical pulse generating device may include a pulse laser that outputs an optical pulse train, a first optical delay line that generates the first optical pulse train and the second optical pulse train having different phases, based on the optical pulse train, and a second optical delay line that generates the third optical pulse train and the fourth optical pulse train having different phases, based on the optical pulse train.

In an example embodiment, the CDN detector may include a first clock timing detector that detects a first edge timing of the first clock, and a second clock timing detector that detects a second edge timing of the second clock, and the control logic may control a first delay time of the first optical delay line and a second delay time of the second optical delay line based on a skew between the first clock and the second clock, which is determined based on the first edge timing and the second edge timing.

### BRIEF DESCRIPTION OF THE FIGURES

The above and other objects and features of the inventive concept will become apparent by describing in detail exemplary embodiments thereof with reference to the accompanying drawings.

FIG. 1 is a block diagram illustrating a clock system according to an example embodiment of the inventive concepts.

FIG. 2 is a diagram illustrating an example of a current pulse generator and an integrated circuit according to an example embodiment of the inventive concepts.

FIG. 3 is a circuit diagram illustrating an equivalent model of a circuit of FIG. 2.

FIG. 4 is a block diagram illustrating a clock system of FIG. 1 in detail.

FIG. 5 is a block diagram illustrating an example of an optical pulse generating device of FIG. 4 for regulating a current of a current pulse train.

FIG. 6 is a block diagram illustrating an example of a current pulse generator of FIG. 4 for regulating a current of a current pulse train.

FIG. 7 is a block diagram illustrating a clock system according to an example embodiment of the inventive concepts.

FIG. 8 illustrates a block diagram of a clock system of FIG. 7 for reducing a skew between clocks.

FIG. 9 is a diagram illustrating a structure of a semiconductor device according to an example embodiment of the inventive concepts.

FIG. 10 is a block diagram illustrating a clock system according to another example embodiment of the inventive concepts.

### DETAILED DESCRIPTION

Hereinafter, example embodiments of the inventive concepts are described in detail with reference to the accompanying drawings. In the following description, specific details such as detailed components and structures are merely provided to assist the overall understanding of the example embodiments of the inventive concepts. Therefore, it should be apparent to those skilled in the art that various changes and modifications of the example embodiments described herein may be made without departing from the scope and spirit of the present invention. In addition, descriptions of well-known functions and structures are omitted for clarity and conciseness. The terms described below are terms defined in consideration of the functions in the inventive concept and are not limited to a specific function. The definitions of the terms should be determined based on the contents throughout the specification.

In the following drawings or in the detailed description, modules may be illustrated in a drawing or may be connected with any other components other than components in the detailed description. Modules or components may be connected directly or indirectly. Modules or components may be connected through communication or may be physically connected.

Unless defined differently, all terms used herein, which include technical terminologies or scientific terminologies, have the same meaning as that understood by a person skilled in the art to which the present invention belongs. Terms defined in a generally used dictionary are to be interpreted to have meanings equal to the contextual meanings in a relevant technical field, and are not interpreted to have ideal or excessively formal meanings unless clearly defined in the specification.

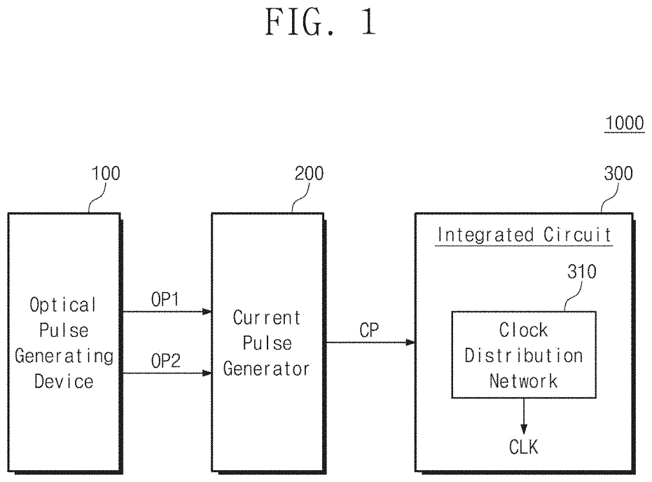

FIG. 1 is a block diagram illustrating a clock system according to an example embodiment of the inventive concepts. Referring to FIG. 1, a clock system 1000 may include an optical pulse generating device 100, a current pulse generator 200, and an integrated circuit 300. The current pulse generator 200 and the integrated circuit 300 may be included in one semiconductor device. In this case, the current pulse generator 200 and the integrated circuit 300 may be implemented with one chip (i.e., may be implemented in the form of an on-chip) or may be implemented with separate chips (i.e., may be implemented in the form of an off-chip).

The optical pulse generating device 100 may generate an optical pulse train. The optical pulse generating device 100 may include a pulse laser for generating the optical pulse train. For example, the optical pulse train may be a femtosecond or picosecond optical pulse train. In this case, the femtosecond or picosecond optical pulse train may have low timing jitter, short pulse width, and high peak power characteristics.

As illustrated in FIG. 1, the optical pulse generating device 100 may generate a first optical pulse train OP1 and a second optical pulse train OP2. When the period of the first optical pulse train OP1 is the same as the period of the second optical pulse train OP2, a phase difference of the first optical pulse train OP1 and the second optical pulse train OP2 may be half the period. For example, the optical pulse generating device 100 may divide the optical pulse train generated from the pulse laser into the first optical pulse train OP1 and the second optical pulse train OP2. The optical pulse generating device 100 may delay one of the first optical pulse train OP1 and the second optical pulse train OP2 such that a phase difference of the first optical pulse train OP1 and the second optical pulse train OP2 is half the period. As such, the optical pulse generating device 100 may output the first and second optical pulse trains OP1 and OP2 having a phase difference of half the period. The first and second optical pulse trains OP1 and OP2 may be provided to the current pulse generator 200.

The current pulse generator 200 may generate a current pulse train CP based on the optical pulse trains OP1 and OP2. The current pulse generator 200 may include photodiodes for converting an optical pulse into a current pulse. The current pulse train CP may be generated from the optical pulse trains OP1 and OP2 through the photodiodes. For example, the current pulse train CP that is generated from the femtosecond or picosecond optical pulse trains OP1 and OP2 may have a low jitter and charges of several picoCoulomb (pC) or more. The current pulse train CP may be provided to the integrated circuit 300.

The integrated circuit 300 may include circuit blocks (not illustrated) where semiconductor elements are integrated. The integrated circuit 300 may perform a certain function or various functions through the circuit blocks. For example, the integrated circuit 300 may be implemented with a processor, a system on chip (SoC), an LSI chip, or the like, but the inventive concepts are not limited thereto.

The integrated circuit 300 may include a clock distribution network 310. The clock distribution network 310 may output a clock CLK for synchronizing the circuit blocks of the integrated circuit 300. The clock CLK output from the clock distribution network 310 may be provided to the circuit blocks of the integrated circuit 300, and the circuit blocks may operate based on the clock CLK.

The clock distribution network 310 may be driven based on the current pulse train CP to generate the clock CLK. For example, the clock distribution network 310 may operate like one capacitor based on the current pulse train CP. In this case, the clock distribution network 310 may be charged and discharged depending on the current pulse train CP and may generate the clock CLK.

The clock distribution network 310 may not include clock drivers (or repeaters) for transferring the clock CLK to the circuit blocks. When the clock distribution network 310 does not include the clock drivers, jitter, skew, power consumption, and heat generation issues due to the clock drivers may decrease. As such, a timing jitter and a skew of the clock CLK that is provided to each circuit block of the integrated circuit 300 according to an example embodiment of the inventive concepts may be minimized, and power consumption of the integrated circuit 300 may decrease.

As described above, the clock system 1000 according to an example embodiment of the inventive concepts may generate the current pulse train CP having a low timing jitter characteristic based on the optical pulse trains OP1 and OP2 having a low timing jitter characteristic. The clock CLK that is generated based on this current pulse train CP may also have a low timing jitter characteristic.

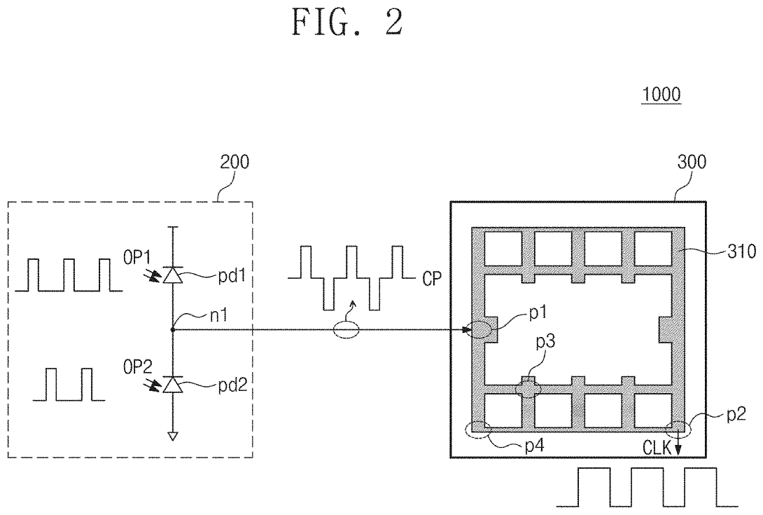

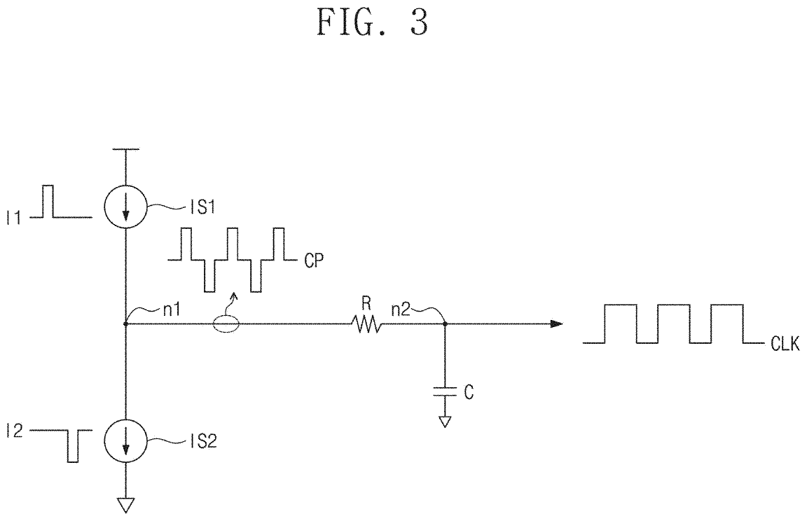

Below, the current pulse generator 200 and the integrated circuit 300 will be more fully described with reference to FIGS. 2 and 3.

FIG. 2 is a diagram illustrating an example of a current pulse generator and an integrated circuit according to an example embodiment of the inventive concepts. Referring to FIG. 2, the current pulse generator 200 may include a first photodiode pd1 and a second photodiode pd2. The first photodiode pd1 may receive the first optical pulse train OP1, and the second photodiode pd2 may receive the second optical pulse train OP2. As illustrated in FIG. 2, a phase difference of the first optical pulse train OP1 and the second optical pulse train OP2 may be half the period. Each of the first and second photodiodes pd1 and pd2 may convert the corresponding optical pulse train into an electrical signal. As such, the current pulse train CP may be output from a node n1 between the first photodiode pd1 and the second photodiode pd2.

As illustrated in FIG. 2, the integrated circuit 300 may include the clock distribution network 310 that is implemented with a metal layer of a grid shape (or a mesh structure, an H-tree structure, or a combination thereof). The current pulse train CP may be provided to a first point p1 of the clock distribution network 310. As the current pulse train CP is provided, the clock CLK may be output from the clock distribution network 310. The output clock CLK may be provided to the circuit blocks that perform a certain function of the integrated circuit 300.

An example is illustrated in FIG. 2 as the clock CLK is output from a second point p2 of the clock distribution network 310, but the inventive concepts are not limited thereto. For example, when the current pulse train CP is provided, the clocks CLK may be output from a plurality of points (e.g., a third point p3 and a fourth point p3) of the clock distribution network 310. The clocks CLK that are output from different points may be provided to different circuit blocks. That is, the clocks CLK may be provided to various circuit blocks of the integrated circuit 300 based on the one clock distribution network 310.

FIG. 3 is a circuit diagram illustrating an equivalent model of a circuit of FIG. 2. Referring to FIGS. 2 and 3, the first photodiode pd1 may be modeled as a first current source IS1, the second photodiode pd2 as a second current source IS2, and the clock distribution network 310 as a resistor “R” and a capacitor “C”.

The first photodiode pd1 may generate a first current I1 that is used to charge the capacitor “C”, based on the first optical pulse train OP1. As such, the first photodiode pd1 may be modeled as the first current source IS1 that generates the first current I1. Because a phase difference of the first optical pulse train OP1 and the second optical pulse train OP2 is half the period, the second photodiode pd2 may not generate any current at a time when the first photodiode pd1 generates the first current I1. The second photodiode pd2 may generate a second current I2 that is used to discharge the capacitor “C”, based on the second optical pulse train OP2. As such, the second photodiode pd2 may be modeled as the second current source IS2 that generates the second current I2. Because a phase difference of the first optical pulse train OP1 and the second optical pulse train OP2 is half the period, the first photodiode pd1 may not generate any current at a time when the second photodiode pd2 generates the second current I2. As such, the current pulse train CP may be generated based on the first current I1 and the second current I2 generated from the first current source IS1 and the second current source IS2, and the current pulse train CP may be output from the node n1. The capacitor “C” may be periodically charged and discharged by the current pulse train CP.

As the capacitor “C” is periodically charged and discharged, a voltage that is output from a node n2 may periodically change. As such, the clock CLK may be generated based on the voltage output from the node n2. That is, when the current pulse train CP is provided, the clock CLK may be output from any node (e.g., n2) of the clock distribution network 310.

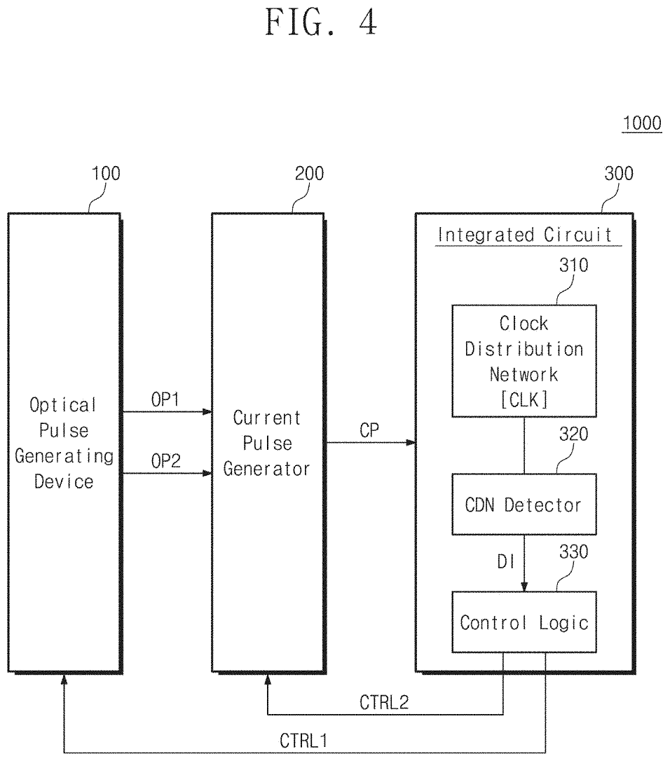

FIG. 4 is a block diagram illustrating a clock system of FIG. 1 in detail. An operation of the clock system 1000 of FIG. 4 may be the same as or substantially similar to the operation of the clock system 1000 of FIG. 1, and thus, additional description will be omitted to avoid redundancy.

The integrated circuit 300 may include the clock distribution network 310, a clock distribution network (CDN) detector 320, and control logic 330. The CDN detector 320 may detect (or obtain) a variety of information associated with the clock distribution network 310. For example, the CDN detector 320 may detect (or obtain) status information of the clock distribution network 310, such as load capacitance information, effective resistance information, or temperature information, or may detect the clock CLK output from the clock distribution network 310. The CDN detector 320 may provide detection information DI to the control logic 330.

The control logic 330 may generate at least one of a first control signal CTRL1 and a second control signal CTRL2, based on the detection information DI. The control logic 330 may regulate a current intensity (hereinafter referred to as a “current”) of the current pulse train CP based on at least one of the first control signal CTRL1 and the second control signal CTRL2.

For example, the control logic 330 may provide the first control signal CTRL1 to the optical pulse generating device 100 and may control optical intensities of the optical pulse trains OP1 and OP2 generated from the optical pulse generating device 100. Thus, at least one of an optical intensity of the first optical pulse train OP1 and an optical intensity of the second optical pulse train OP2 may be controlled by the first control signal CTRL1. When at least one of the optical intensity of the first optical pulse train OP1 and the optical intensity of the second optical pulse train OP2 changes, the current of the current pulse train CP may change. For example, when the optical intensity of the first optical pulse train OP1 is controlled, a magnitude of a positive peak voltage of the current pulse train CP may change. When the optical intensity of the second optical pulse train OP2 is controlled, a magnitude of a negative peak voltage of the current pulse train CP may change. That is, the control logic 330 may control the optical intensities of the optical pulse trains OP1 and OP2 to indirectly regulate the current of the current pulse train CP.

Also, the control logic 330 may provide the second control signal CTRL2 to the current pulse generator 200 and may directly control the current of the current pulse train CP.

The capacitance or effective resistance of the clock distribution network 310 may be increased due to various causes such as an increase in a temperature of the integrated circuit 300, a change of a workload of the integrated circuit 300, a change of a clock load due to an on/off of a certain circuit region of the integrated circuit 300 (e.g., a change of a clock load occurring as some circuits or some circuit blocks of the integrated circuit 300 are enabled/disabled through clock gating). In this case, a delay of the clock CLK may be increased, and thus, the current of the current pulse train CP necessary to drive the clock distribution network 310 may be increased. Accordingly, the control logic 330 may regulate the current of the current pulse train CP depending on the load capacitance information, the effective resistance information, or the temperature information. For example, when the load capacitance information, the effective resistance information, or the temperature information provided from the CDN detector 320 indicates a load capacitance, an effective resistance, or a temperature is increased, the control logic 330 may generate at least one of the first control signal CTRL1 and the second control signal CTRL2 depending on the increment of the load capacitance, the effective resistance, or the temperature and may increase the current of the current pulse train CP.

When a peak voltage of the clock CLK output from the clock distribution network 310 is different from a reference voltage, the circuit blocks of the integrated circuit 300 may operate abnormally based on the provided clock CLK. Accordingly, the control logic 330 may regulate the current of the current pulse train CP depending on voltage information of the clock CLK provided from the CDN detector 320. For example, When a peak voltage of the clock CLK output from the clock distribution network 310 is smaller than the reference voltage, the control logic 330 may generate at least one of the first control signal CTRL1 and the second control signal CTRL2 and may increase the current of the current pulse train CP. As such, the peak voltage of the clock CLK output from the clock distribution network 310 may be increased.

For example, the control logic 330 may receive information about a positive peak voltage and a negative peak voltage of the clock CLK from the CDN detector 320. When the positive peak voltage of the clock CLK is different from a first reference voltage, the control logic 330 may control the optical intensity of the first optical pulse train OP1 output from the optical pulse generating device 100 such that the current of the current pulse train CP is regulated. When the negative peak voltage of the clock CLK is different from a second reference voltage, the control logic 330 may control the optical intensity of the second optical pulse train OP2 output from the optical pulse generating device 100 such that the current of the current pulse train CP is regulated.

As described above, the clock system 1000 according to an example embodiment of the inventive concepts may detect (or obtain) a variety of information associated with the clock distribution network 310 and may adaptively regulate the current of the current pulse train CP based on the detection information DI. Accordingly, even though status information of the clock distribution network 310 having an influence on the clock CLK changes, the desired clock CLK may be provided to the circuit blocks of the integrated circuit 300. Also, even though the clock CLK is output from any point of the clock distribution network 310, the desired clock CLK may be provided to the circuit blocks of the integrated circuit 300.

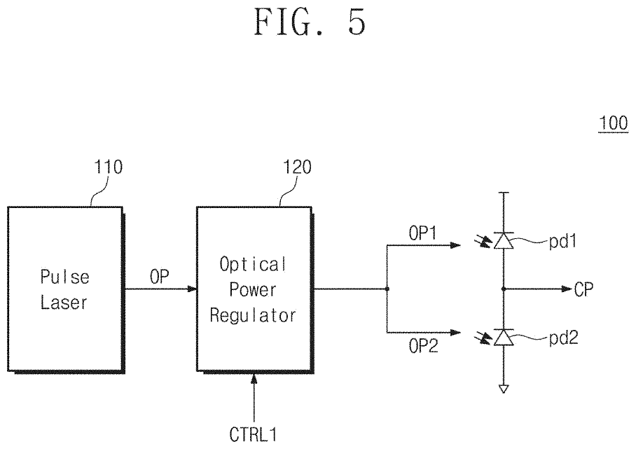

FIG. 5 is a block diagram illustrating an example of an optical pulse generating device of FIG. 4 for regulating a current of a current pulse train. Referring to FIG. 5, the optical pulse generating device 100 may include a pulse laser 110 and an optical power regulator 120.

The pulse laser 110 may generate an optical pulse train OP. The optical pulse train OP may be provided to the optical power regulator 120. The optical power regulator 120 may regulate the optical intensity of the optical pulse train OP in response to the first control signal CTRL1. For example, the optical power regulator 120 may regulate an optical intensity of at least one of the first optical pulse train OP1 and the second optical pulse train OP2 in response to the first control signal CTRL1. For example, when the optical intensity of the first optical pulse train OP1 is regulated, a current that is generated from the first photodiode pd1 may change. When the optical intensity of the second optical pulse train OP2 is regulated, a current that is generated from the second photodiode pd2 may change. Accordingly, the current of the current pulse train CP that is output to the clock distribution network 300 may be regulated.

When the optical intensity of the first optical pulse train OP1 and the optical intensity of the second optical pulse train OP2 are controlled independently of each other, an unintended waveform of the clock CLK may be prevented from being generated due to the mismatch of the first photodiode pd1 and the second photodiode pd2.

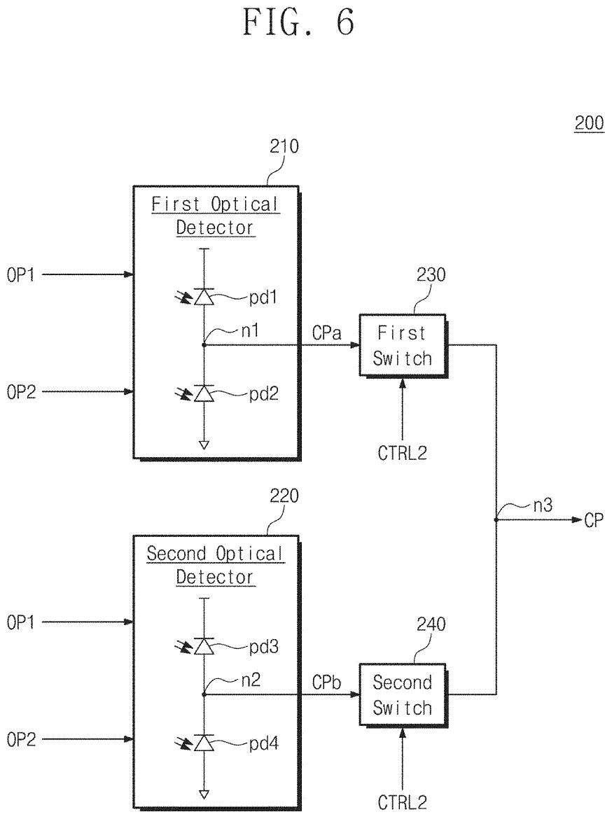

FIG. 6 is a block diagram illustrating an example of a current pulse generator of FIG. 4 for regulating a current of a current pulse train. Referring to FIG. 6, the current pulse generator 200 may include a first optical detector 210, a second optical detector 220, a first switch 230, and a second switch 240.

The first optical detector 210 may include the first photodiode pd1 and the second photodiode pd2. The first photodiode pd1 may receive the first optical pulse train OP1, and the second photodiode pd2 may receive the second optical pulse train OP2. In this case, as described with reference to FIG. 2, a current pulse train CPa may be output from a node n1 of the first optical detector 210.

The second optical detector 220 may include a third photodiode pd3 and a fourth photodiode pd4. The third photodiode pd3 may receive the first optical pulse train OP1, and the fourth photodiode pd4 may receive the second optical pulse train OP2. In this case, as described with reference to FIG. 2, a current pulse train CPb may be output from a node n2 of the second optical detector 220.

The first switch 230 may selectively output the current pulse train CPa provided from the first optical detector 210, in response to the second control signal CTRL2. For example, when the first switch 230 is turned on in response to the second control signal CTRL2, the first switch 230 may output the current pulse train CPa to a node n3. When the first switch 230 is turned off in response to the second control signal CTRL2, the first switch 230 may not output the current pulse train CPa.

The second switch 240 may selectively output the current pulse train CPb provided from the second optical detector 220, in response to the second control signal CTRL2. For example, when the second switch 240 is turned on in response to the second control signal CTRL2, the second switch 240 may output the current pulse train CPb to the node n3. When the second switch 240 is turned off in response to the second control signal CTRL2, the second switch 240 may not output the current pulse train CPb.

A current of the current pulse train CP that is output from the node n3 may vary depending on an output of the first switch 230 and the second switch 240. For example, when both the first switch 230 and the second switch 240 are turned on, the current of the current pulse train CP output from the node n3 may be a sum of a current of the current pulse train CPa output from the first switch 230 and a current of the current pulse train CPb output from the second switch 240. In this case, the current of the current pulse train CP output from the node n3 may be greater than the current of the current pulse train CP output based on one optical detector.

An example is illustrated in FIG. 6 as the current pulse generator 200 includes two optical detectors, but the inventive concepts are not limited thereto. For example, the current pulse generator 200 may include three or more optical detectors. In this case, as the number of optical detectors increases, the current of the current pulse train CP that the current pulse generator 200 outputs may increase.

As described above, the current pulse generator 200 according to an example embodiment of the inventive concepts may include optical detectors, each of which is implemented with a pair of photodiodes. An output of a current pulse train that is generated from each optical detector may be controlled based on the second control signal CTRL2. In this case, the second control signal CTRL2 corresponding to the first switch 230 and the second control signal CTRL2 corresponding to the first switch 240 may be different or the second control signal CTRL2 may include multiple bits for controlling different switches. As such, the current of the current pulse train CP that is output from the current pulse generator 200 may be regulated. However, the inventive concepts are not limited thereto. For example, the current pulse generator 200 may regulate a current of the current pulse train CP through a separate current regulator.

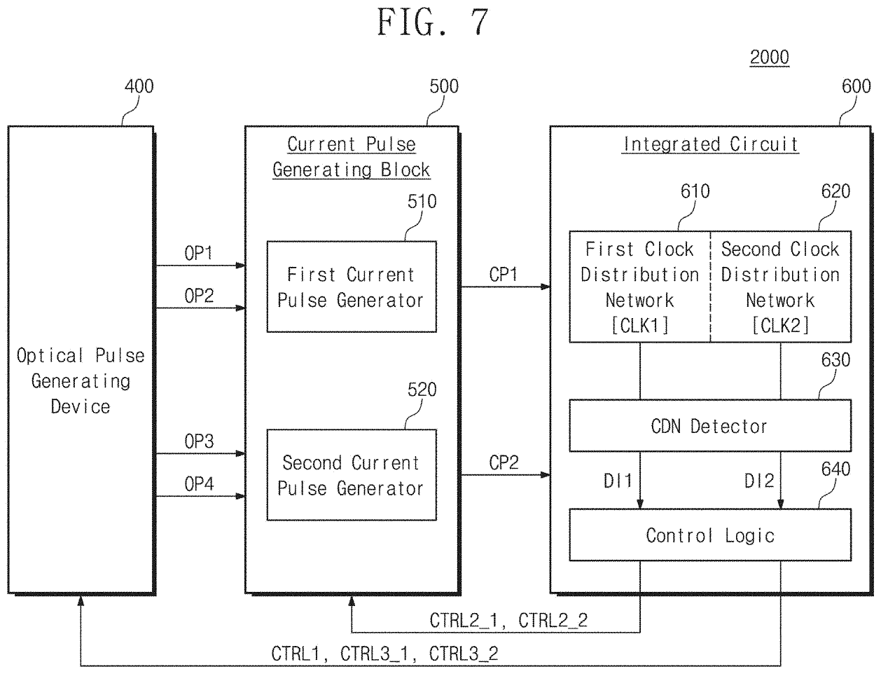

As described with reference to FIGS. 1 to 6, the clock system 1000 may drive the clock distribution network 310 based on one current pulse train CP. However, when the load of circuit blocks performing various functions of the integrated circuit 300 is large, it may be difficult for the clock system 1000 to drive the clock distribution network 310 based on one current pulse train CP. In this case, a clock system according to an example embodiment of the inventive concepts may drive a clock distribution network based on a plurality of current pulse trains. Below, a clock system capable of driving a clock distribution network based on a plurality of current pulse trains will be described with reference to FIGS. 7 to 9.

FIG. 7 is a block diagram illustrating a clock system according to an example embodiment of the inventive concepts. Referring to FIG. 7, a clock system 2000 may include an optical pulse generating device 400, a current pulse generating block 500, and an integrated circuit 600.

The optical pulse generating device 400 may generate first to fourth optical pulse trains OP1 to OP4. A phase difference of the first optical pulse train OP1 and the second optical pulse train OP2 may be half the period, and a phase difference of the third optical pulse train OP3 and the fourth optical pulse train OP4 may be half the period. For example, the first optical pulse train OP1 and the third optical pulse train OP3 may have the same phase, and the second optical pulse train OP2 and the fourth optical pulse train OP4 may have the same phase. The first to fourth optical pulse trains OP1 to OP4 may be provided to the current pulse generating block 500.

The current pulse generating block 500 may include a first current pulse generator 510 and a second current pulse generator 520. The first current pulse generator 510 may generate a first current pulse train CP1 described with reference to FIGS. 2 and 3, based on the first and second optical pulse trains OP1 and OP2. The second current pulse generator 520 may generate a second current pulse train CP2 described with reference to FIGS. 2 and 3, based on the third and fourth optical pulse trains OP3 and OP4. Each of the first and second current pulse generators 510 and 520 may generate a current pulse train through a photodiode pair as described with reference to FIG. 2. The first current pulse train CP1 and the second current pulse train CP2 may be provided to the integrated circuit 600.

The integrated circuit 600 may include a first clock distribution network 610, a second clock distribution network 620, a CDN detector 630, and control logic 640.

Circuit blocks (not illustrated) of the integrated circuit 600 may be divided into first circuit blocks and second circuit blocks depending on functions or loads. When circuit blocks are divided depending on functions, a function of the first circuit blocks and a function of the second circuit blocks may be performed independently of each other. For example, when the integrated circuit 600 includes a plurality of cores, the first circuit blocks may constitute a first core, and the second circuit blocks may constitute a second core. However, the inventive concepts are not limited thereto. For example, the first circuit blocks may constitute a memory, and the second circuit blocks may constitute an input/output (I/O) circuit. When circuit blocks are divided depending on loads, the first circuit blocks may correspond to a first load, and the second circuit blocks may correspond to a second load. In this case, at least one function may be performed based on the first circuit blocks and the second circuit blocks.

The first clock distribution network 610 may correspond to the first circuit blocks of the integrated circuit 600, and the second clock distribution network 620 may correspond to the second circuit blocks of the integrated circuit 600. That is, the first clock distribution network 610 and the second clock distribution network 620 may be clock distribution networks that is subdivided from one clock distribution network (e.g., the clock distribution network 310 of FIG. 4) based on the first circuit blocks and the second circuit blocks. In this case, the first clock distribution network 610 may provide a first clock CLK1 to the first circuit blocks, and the second clock distribution network 620 may provide a second clock CLK2 to the second circuit blocks.

The first clock distribution network 610 may generate the first clock CLK1 based on the first current pulse train CP1, and the second clock distribution network 620 may generate the second clock CLK2 based on the second current pulse train CP2. Thus, the first clock distribution network 610 may be driven by the first current pulse train CP1, and the second clock distribution network 620 may be driven by the second current pulse train CP2.

The CDN detector 630 may detect (or obtain) a variety of information associated with the first and second clock distribution networks 610 and 620. For example, the CDN detector 630 may detect status information of each of the first and second clock distribution networks 610 and 620, such as load capacitance information, effective resistance information, or temperature information, and clocks output from the first and second clock distribution networks 610 and 620. The CDN detector 630 may provide first detection information DI1 of the first clock distribution network 610 and second detection information DI2 of the second clock distribution network 620 to the control logic 640.

The control logic 640 may generate at least one of the first control signal CTRL1, a second control signal CTRL2_1, and a third control signal CTRL3_1, based on the first detection information DI1. The control logic 640 may provide the first control signal CTRL1 and the third control signal CTRL3_1 to the optical pulse generating device 400, and may provide the second control signal CTRL2_1 to the first current pulse generator 510. The control logic 640 may regulate a current of the first current pulse train CP1, which is provided to the first clock distribution network 610, based on at least one of the first control signal CTRL1 and the second control signal CTRL2_1. The control logic 640 may regulate a timing of the first current pulse train CP1, which is provided to the first clock distribution network 610, by delaying the first optical pulse train OP1 and the second optical pulse train OP2 based on the third control signal CTRL3_1. For example, as described with reference to FIG. 5, the optical pulse generating device 400 may control an optical intensity of at least one of the first optical pulse train OP1 and the second optical pulse train OP2 based on the first control signal CTRL1. When an optical intensity of at least one of the first optical pulse train OP1 and the second optical pulse train OP2 changes, the current of the first current pulse train CP1 may change. Alternatively, as described with reference to FIG. 6, the first current pulse generator 510 may regulate the current of the first current pulse train CP1 based on the second control signal CTRL2_1.

The control logic 640 may generate at least one of the first control signal CTRL1, a second control signal CTRL2_2, and a third control signal CTRL3_2, based on the second detection information DI2. The control logic 640 may provide the first control signal CTRL1 and the third control signal CTRL3_2 to the optical pulse generating device 400, and may provide the second control signal CTRL2_2 to the second current pulse generator 520. The control logic 640 may regulate a current of the second current pulse train CP2, which is provided to the second clock distribution network 620, based on at least one of the first control signal CTRL1 and the second control signal CTRL2_2. The control logic 640 may regulate a timing of the second current pulse train CP2, which is provided to the second clock distribution network 620, by delaying the third optical pulse train OP3 and the fourth optical pulse train OP4 based on the third control signal CTRL3_2.

When the clocks CLK1 and CLK2 are output from the first and second clock distribution networks 610 and 620, a skew may occur between the clocks CLK1 and CLK2 due to various causes such as a temperature difference between the first and second clock distribution networks 610 and 620. When the control logic 640 regulates a timing of the current pulse trains CP1 and CP2 based on the third control signals CTRL3_1 and CTRL3_2, a skew between the clocks CLK1 and CLK2 that are output from the current pulse trains CP1 and CP2 may be minimized. Thus, the control logic 640 may generate the third control signals CTRL3_1 and CTRL3_2 such that a skew between the clocks CLK1 and CLK2 is minimized.

An example is illustrated in FIG. 7 as the clock system 2000 includes two current pulse generators 510 and 520 and two clock distribution networks 610 and 620, but the inventive concepts are not limited thereto. The clock system 2000 may include current pulse generators and clock distribution networks, the numbers of which are variously determined depending on functions or loads of the circuit blocks of the integrated circuit 600.

As described above, when one clock distribution network is divided into a plurality of clock distribution networks, the clock system 2000 may drive the clock distribution networks based on a plurality of current pulse trains. In this case, the clock system 2000 may receive detection information from the clock distribution networks and may regulate currents and timings of the current pulse trains to be provided to the clock distribution networks, respectively. Accordingly, the clock system 2000 may drive the whole of the clock distribution network of the integrated circuit 600 more efficiently.

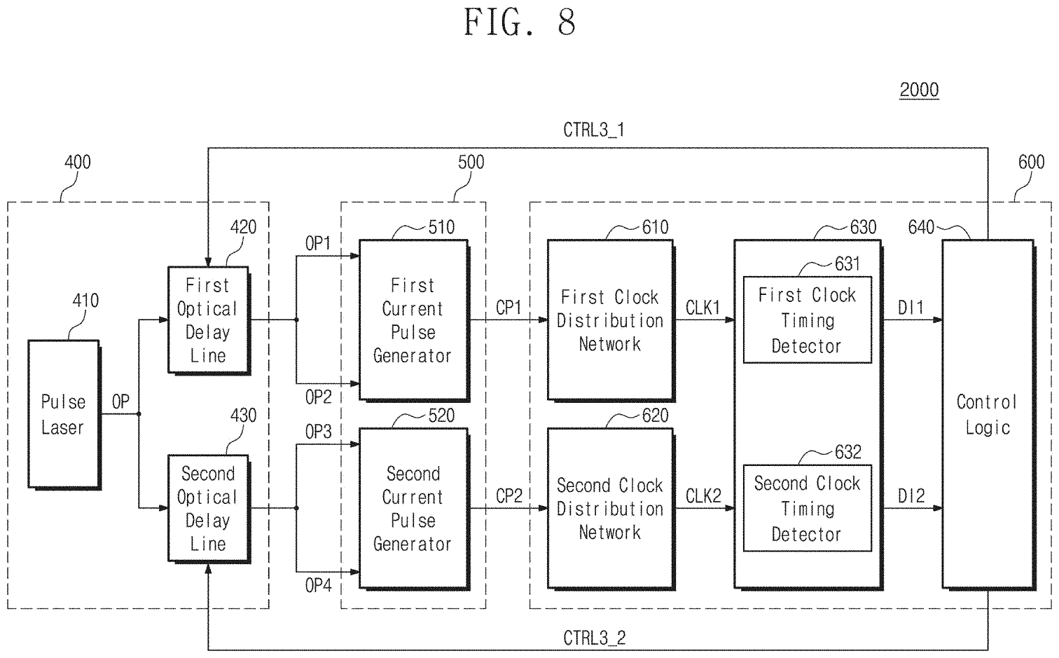

Below, the clock system 2000 for reducing a skew between the clocks CLK1 and CLK2 will be in detail described with reference to FIG. 8.

FIG. 8 illustrates a block diagram of a clock system of FIG. 7 for reducing a skew between clocks. Referring to FIG. 8, the clock system 2000 may include the optical pulse generating device 400, the current pulse generating block 500, and the integrated circuit 600.

The optical pulse generating device 400 may include a pulse laser 410, a first optical delay line 420, and a second optical delay line 430. The pulse laser 410 may generate the optical pulse train OP and may provide the generated optical pulse train OP to the first optical delay line 420 and the second optical delay line 430. The first optical delay line 420 may delay the received optical pulse train OP in response to the third control signal CTRL3_1, and the second optical delay line 430 may delay the received optical pulse train OP in response to the third control signal CTRL3_2. For example, each of the first and second optical delay lines 420 and 430 may be implemented with an actuator such as an optical delay shifter, but the inventive concepts are not limited thereto.

The first optical delay line 420 may generate the first optical pulse train OP1 and the second optical pulse train OP2 based on the delayed optical pulse train OP. The first optical delay line 420 may provide the first optical pulse train OP1 and the second optical pulse train OP2 to the first current pulse generator 510. The second optical delay line 430 may generate the third optical pulse train OP3 and the fourth optical pulse train OP4 based on the delayed optical pulse train OP. The second optical delay line 430 may provide the third optical pulse train OP3 and the fourth optical pulse train OP4 to the second current pulse generator 520.

The first current pulse generator 510 may generate the first current pulse train CP1 based on the first and second optical pulse trains OP1 and OP2. The second current pulse generator 520 may generate the second current pulse train CP2 based on the third and fourth optical pulse trains OP3 and OP4.

The integrated circuit 600 may include the first clock distribution network 610, the second clock distribution network 620, the CDN detector 630, and the control logic 640. The CDN detector 630 may include a first clock timing detector 631 and a second clock timing detector 632.

The first clock distribution network 610 may output the first clock CLK1 based on the first current pulse train CP1. The first clock timing detector 631 may detect an edge timing of at least one of a rising edge and a falling edge of the first clock CLK1 output from the first clock distribution network 610. The first clock timing detector 631 may provide the control logic 640 with the first detection information DI1 about the edge timing of the first clock CLK1.

The second clock distribution network 620 may output the second clock CLK2 based on the second current pulse train CP2. The second clock timing detector 632 may detect an edge timing of at least one of a rising edge and a falling edge of the second clock CLK2 output from the second clock distribution network 620. The second clock timing detector 632 may provide the control logic 640 with the second detection information DI2 about the edge timing of the second clock CLK2.

For example, each of the first and second clock timing detectors 631 and 632 may be implemented with a time-to-digital converter (TDC). However, the inventive concepts are not limited thereto.

The control logic 640 may receive the first detection information DI1 and the second detection information DI2. The control logic 640 may compare the first detection information DI1 and the second detection information DI2 to determine a skew between the first clock CLK1 and the second clock CLK2. The control logic 640 may generate the third control signals CTRL3_1 and CTRL3_2 based on the determined skew such that the skew is minimized. For example, when the rising edge of the second clock CLK2 is advanced with respect to the rising edge of the first clock CLK1 as much as a first time, the control logic 640 may generate the third control signal CTRL3_2 such that the optical pulse train OP is further delayed through the second optical delay line 430 as much as the first time. The control logic 640 may provide the third control signal CTRL3_1 to the first optical delay line 420 to control the first optical delay line 420 and may provide the third control signal CTRL3_2 to the second optical delay line 430 to control the second optical delay line 430.

As described above, the clock system 2000 may detect a skew between the clocks CLK1 and CLK2 output from the first and second clock distribution networks 610 and 620 and may control a delay amount of an optical path depending on the detected skew. Accordingly, a skew between the clocks CLK1 and CLK2 output from the first and second clock distribution networks 610 and 620 may be minimized, and circuit blocks of the integrated circuit 600 may be operated without an error.

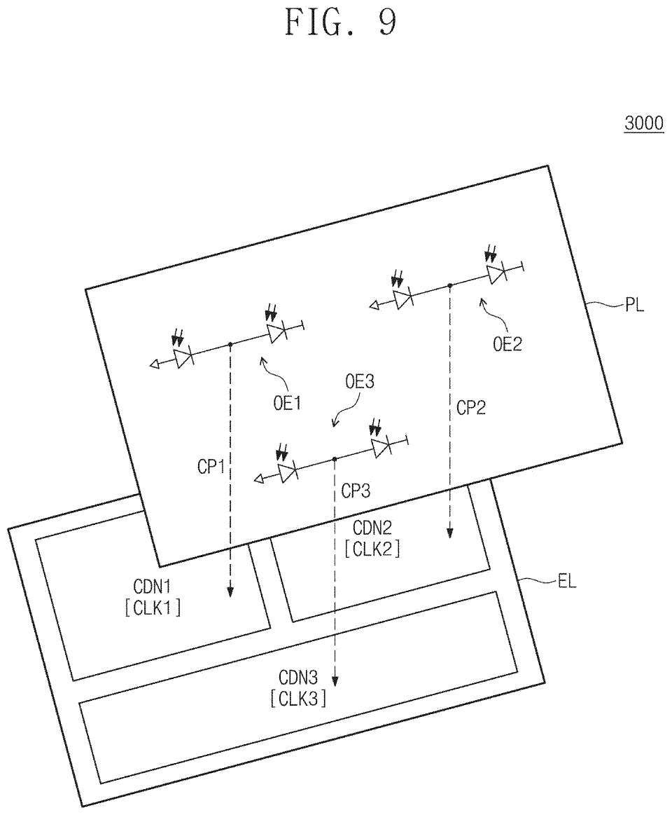

FIG. 9 is a diagram illustrating a structure of a semiconductor device according to an example embodiment of the inventive concepts. Referring to FIG. 9, a semiconductor device 3000 may be implemented with one chip. The semiconductor device 3000 may include an optical chip layer PL and an electronic chip layer EL. First to third optical elements OE1 to OE3, each of which includes a pair of photodiodes, may be disposed in the optical chip layer PL. First to third clock distribution networks CDN1 to CDN3 may be disposed in the electronic chip layer EL. In this case, the first to third optical elements OE1 to OE3 may correspond to the first to third clock distribution networks CDN1 to CDN3, respectively. For example, as illustrated in FIG. 9, the optical chip layer PL and the electronic chip layer EL may form a vertically stacked structure. However, the inventive concepts are not limited thereto. The optical chip layer PL and the electronic chip layer EL may form an abutted structure in which the optical chip layer PL and the electronic chip layer EL are abutted in a line.

The first optical element OE1 may generate the first current pulse train CP1 based on the optical pulse train. The first current pulse train CP1 thus generated may be provided to the first clock distribution network CDN1. The first clock distribution network CDN1 may output the first clock CLK1 based on the first current pulse train CP1. The second optical element OE2 may generate the second current pulse train CP2 based on the optical pulse train. The second current pulse train CP2 thus generated may be provided to the second clock distribution network CDN2. The second clock distribution network CDN2 may output the second clock CLK2 based on the second current pulse train CP2. Likewise, the third optical element OE3 may generate a third current pulse train CP3 based on the optical pulse train. The third current pulse train CP3 thus generated may be provided to the third clock distribution network CDN3. The third clock distribution network CDN3 may output a third clock CLK3 based on the third current pulse train CP3.

An example is illustrated in FIG. 9 as three optical elements OE1 to OE3 are disposed in the optical chip layer PL and three clock distribution networks CDN1 to CDN3 are disposed in the electronic chip layer EL, but the inventive concepts are not limited thereto. For example, the number of optical elements that are disposed in the optical chip layer PL of the semiconductor device 3000 may be variously determined, and the number of clock distribution networks that are disposed in the electronic chip layer EL may be determined to correspond to the number of optical elements disposed in the optical chip layer PL.

As described above, optical elements and clock distribution networks may be disposed on one chip in different layers. Accordingly, optical elements may be easily disposed to correspond to locations of the clock distribution networks of the semiconductor device 3000. Also, because the optical chip layer PL is separately added, a chip design where electronic circuits of the semiconductor device 3000 are placed may not be changed.

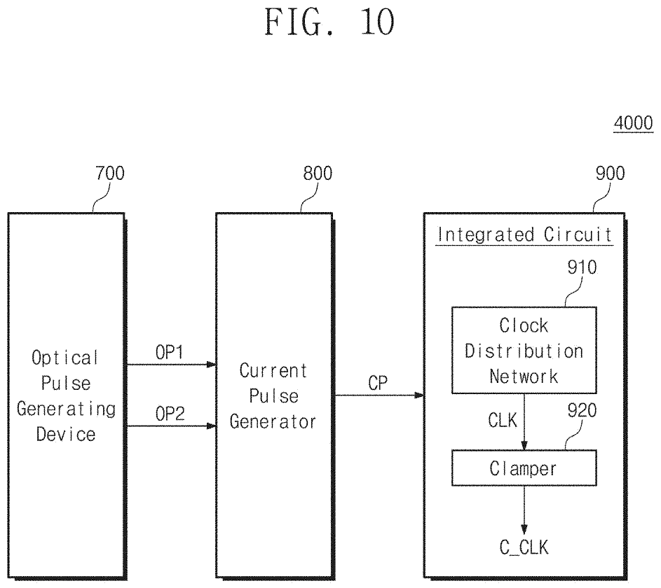

FIG. 10 is a block diagram illustrating a clock system according to another example embodiment of the inventive concepts. Referring to FIG. 10, a clock system 4000 may include an optical pulse generating device 700, a current pulse generator 800, and an integrated circuit 900. The optical pulse generating device 700, the current pulse generator 800, and the integrated circuit 900 may be similar to the optical pulse generating device 100, the current pulse generator 200, and the integrated circuit 300, and thus, additional description will be omitted to avoid redundancy.

The integrated circuit 900 may include a clock distribution network 910 and a clamper 920. The clock distribution network 910 may receive the current pulse train CP from the current pulse generator 800. The clock distribution network 910 may output the clock CLK based on the current pulse train CP. The clock CLK may be provided to the clamper 920. The clamper 920 may clamp a voltage of the clock CLK such that a maximum voltage of the clock CLK is smaller than a first reference voltage and a minimum voltage of the clock CLK is greater than a second voltage. As such, a clamped clock C_CLK may be output from the clamper 920. The clamped clock C_CLK may be provided to circuit blocks of the integrated circuit 900. For example, the clamper 920 may include a pair of diodes connected in series, but the inventive concepts are not limited thereto.

As described above, in the case where the clock CLK output from the clock distribution network 910 is clamped by the clamper 920, a voltage of the clock CLK may not be out of a desired range due to the mismatch of a pair of photodiodes of the current pulse generator 800.

According to an example embodiment of the inventive concepts, because a clock distribution network does not include clock drivers, there may be provided a semiconductor device and a clock system capable of minimizing jitter, skew, and power consumption issues.

Also, according to an example embodiment of the inventive concepts, there may be provided a semiconductor device and a clock system capable of outputting a clock that the clock distribution network intends, by adaptively controlling a current to be provided to the clock distribution network.

While the inventive concepts has been described with reference to example embodiments thereof, it will be apparent to those of ordinary skill in the art that various changes and modifications may be made thereto without departing from the spirit and scope of the inventive concepts as set forth in the following claims.

What is claimed is:

1. A semiconductor device comprising:
a current pulse generator configured to generate a current pulse train based on a first optical pulse train and a second optical pulse train having different phases;
a clock distribution network configured to output a clock based on the current pulse train;
a clock distribution network (CDN) detector configured to detect at least one of status information of the clock distribution network and the output clock to generate detection information; and
control logic configured to generate a control signal for regulating a current of the current pulse train based on the detection information.

2. The semiconductor device of claim 1, wherein the current pulse generator includes:
a first photodiode configured to generate a first current based on the first optical pulse train; and
a second photodiode configured to generate a second current based on the second optical pulse train, and
wherein the current pulse train is generated based on the first current and the second current.

3. The semiconductor device of claim 1, wherein the current pulse generator includes:
a first optical detector configured to generate a first current pulse train based on the first optical pulse train and the second optical pulse train;
a first switch configured to selectively output the first current pulse train based on the control signal;
a second optical detector configured to generate a second current pulse train based on the first optical pulse train and the second optical pulse train; and
a second switch configured to selectively output the second current pulse train based on the control signal, and
wherein the current pulse train is generated based on a signal output from the first switch and the second switch.

4. The semiconductor device of claim 1, wherein the status information of the clock distribution network includes at least one of load capacitance information, effective resistance information, and temperature information of the clock distribution network.

5. The semiconductor device of claim 1, wherein the CDN detector detects a peak voltage of the output clock.

6. The semiconductor device of claim 5, wherein the control logic generates the control signal based on a result of comparing the peak voltage of the clock and a reference magnitude.

7. The semiconductor device of claim 1, further comprising:
a clamper configured to output a clock clamped such that a positive peak voltage of the output clock is maintained at a first reference voltage or smaller and a negative peak voltage of the output clock is maintained at a second reference voltage or greater.

8. The semiconductor device of claim 1, wherein the clock distribution network is implemented with a metal layer having a mesh structure, an H-tree structure, or a combination thereof.

9. The semiconductor device of claim 1, wherein the clock distribution network is a repeater-free clock distribution network.

10. The semiconductor device of claim 1, wherein the current pulse generator and the clock distribution network are disposed on a single chip including an optical chip layer and an electronic chip layer of a stacked structure or an abutted structure, and
wherein the current pulse generator is disposed in the optical chip layer and the clock distribution network is disposed in the electronic chip layer.

11. The semiconductor device of claim 1, wherein, when the first optical pulse train and the second optical pulse train have a first period, a phase difference of the first optical pulse train and the second optical pulse train is half the first period.

12. A clock system comprising:
an optical pulse generating device configured to generate a first optical pulse train and a second optical pulse train having different phases;
a current pulse generator configured to generate a current pulse train based on the first optical pulse train and the second optical pulse train;
a clock distribution network configured to output a clock based on the current pulse train;
a CDN detector configured to detect at least one of status information of the clock distribution network and the output clock to generate detection information; and
control logic configured to generate a control signal for controlling an optical intensity of at least one of the first optical pulse train and the second optical pulse train based on the detection information.

13. The clock system of claim 12, wherein the optical pulse generating device includes:
a pulse laser configured to output an optical pulse train; and
an optical power regulator configured to generate the first optical pulse train and the second optical pulse train based on the optical pulse train,
wherein the optical power regulator regulates an optical intensity of at least one of the first optical pulse train and the second optical pulse train in response to the control signal.

14. The clock system of claim 13, wherein the output optical pulse train has a pulse width of a femtosecond or picosecond domain.

15. The clock system of claim 12, wherein the status information of the clock distribution network includes at least one of load capacitance information, effective resistance information, and temperature information of the clock distribution network.

16. The clock system of claim 12, wherein the CDN detector detects a peak voltage of the output clock.

17. The clock system of claim 16, wherein the control logic generates the control signal based on a result of comparing the peak voltage of the clock and a reference magnitude.

18. A clock system comprising:
an optical pulse generating device configured to generate first to fourth optical pulse trains;
a first current pulse generator configured to generate a first current pulse train based on the first optical pulse train and the second optical pulse train;
a second current pulse generator configured to generate a second current pulse train based on the third optical pulse train and the fourth optical pulse train;
a first clock distribution network configured to output a first clock based on the first current pulse train;
a second clock distribution network configured to output a second clock based on the second current pulse train;
a CDN detector configured to detect at least one of first status information of the first clock distribution network and the first clock to generate first detection information and to detect at least one of second status information of the second clock distribution network and the second clock to generate second detection information; and
control logic configured to generate a first control signal for regulating a current of the first current pulse train based on the first detection information and to generate a second control signal for regulating a current of the second current pulse train based on the second detection information.

19. The clock system of claim 18, wherein the optical pulse generating device includes:
a pulse laser configured to output an optical pulse train;
a first optical delay line configured to generate the first optical pulse train and the second optical pulse train having different phases, based on the optical pulse train; and
a second optical delay line configured to generate the third optical pulse train and the fourth optical pulse train having different phases, based on the optical pulse train.

20. The clock system of claim 19, wherein the CDN detector includes:
a first clock timing detector configured to detect a first edge timing of the first clock; and
a second clock timing detector configured to detect a second edge timing of the second clock, and
wherein the control logic is further configured to control a first delay time of the first optical delay line and a second delay time of the second optical delay line based on a skew between the first clock and the second clock, which is determined based on the first edge timing and the second edge timing.
